(19) United States
(12) Patent Application Publication
(10) Pub. No.: US 2025/0233085 A1
(43) Pub. Date: Jul. 17, 2025

(54) SEMICONDUCTOR DEVICE

(71) Applicant: Rohm Co., Ltd., Kyoto-shi (JP)

(72) Inventor: Masashi HAYASHIGUCHI, Kyoto-shi (JP)

(21) Appl. No.: 19/170,516

(22) Filed: Apr. 4, 2025

Related U.S. Application Data
(63) Continuation of application No. PCT/JP2023/034653, filed on Sep. 25, 2023.

(30) Foreign Application Priority Data
Oct. 17, 2022 (JP) 2022-166169

(51) Int. Cl. H01L 23/00; H01L 23/31; H01L 23/495; H01L 25/07

(52) U.S. Cl. CPC H01L 23/562; H01L 23/49575; H01L 25/072; H01L 23/3107; H01L 24/40; H01L 2224/40247

(57) ABSTRACT

A semiconductor device includes a first die pad, a first semiconductor element, a sealing resin, and a reinforcement member. The first semiconductor element is bonded to the first die pad. The sealing resin covers the first semiconductor element. The reinforcement member is bonded to the first die pad. The linear expansion coefficient of the reinforcement member is smaller than the linear expansion coefficient of the sealing resin. In one example, the reinforcement member is covered with the sealing resin. The reinforcement member is located on the same side as the first semiconductor element in a first direction with respect to the first die pad.

### TECHNICAL FIELD

The present disclosure relates to semiconductor devices.

### BACKGROUND ART

JP-A-2018-14490 discloses an example of a semiconductor device that includes a first semiconductor element, and a first lead electrically connected to the first semiconductor element. The first semiconductor element is a switching element, such as a MOSFET. The first lead includes a first pad to which the first semiconductor element is electrically bonded, and a first terminal connected to the first pad. DC power that is applied to the first terminal is converted into AC power through the operation of the first semiconductor element.

The semiconductor device disclosed in JP-A-2018-14490 additionally includes a sealing resin covering the first pad and the first semiconductor element. Heat generated by the first semiconductor element is conducted to the first pad, causing greater thermal strain in the first pad than in the sealing resin. This results in thermal stress at the interface between the first pad and the sealing resin. This thermal stress extends to the interface between the first semiconductor element and the sealing resin. When the thermal stress increases, delamination may occur at the interface between the first semiconductor element and the sealing resin, or cracking may occur in the passivation film of the first semiconductor element. It is therefore desirable to provide a measure to reduce the thermal stress.

### BRIEF DESCRIPTION OF THE DRAWINGS

FIG. 1 is a perspective view of a semiconductor device according to a first embodiment of the present disclosure.

FIG. 2 is a plan view of the semiconductor device shown in FIG. 1, with a sealing resin shown as transparent.

FIG. 3 is a plan view corresponding to FIG. 2, with a first conductive member and a second conductive member also shown as transparent.

FIG. 4 is a bottom view of the semiconductor device shown in FIG. 1.

FIG. 5 is a front view of the semiconductor device shown in FIG. 1.

FIG. 6 is a right-side view of the semiconductor device shown in FIG. 1.

FIG. 7 is a sectional view taken along line VII-VII in FIG. 3.

FIG. 8 is a sectional view taken along line VIII-VIII in FIG. 3.

FIG. 9 is a sectional view taken along line IX-IX in FIG. 3.

FIG. 10 is a partially enlarged view of FIG. 7, showing a portion around the first semiconductor element.

FIG. 11 is a partially enlarged view of FIG. 7, showing a portion around the second semiconductor element.

FIG. 12 is a partially enlarged view of FIG. 8.

FIG. 13 is a partially enlarged view of FIG. 9.

FIG. 14 is a partially enlarged view of FIG. 3.

FIG. 15 is a plan view of a semiconductor device according to a second embodiment of the present disclosure, with a first conductive member, a second conductive member, and a sealing resin shown as transparent.

FIG. 16 is a partially enlarged view of FIG. 15.

FIG. 17 is a plan view of a semiconductor device according to a third embodiment of the present disclosure, with a first conductive member, a second conductive member, and a sealing resin shown as transparent.

FIG. 18 is a partially enlarged view of FIG. 17.

FIG. 19 is a plan view of a semiconductor device according to a fourth embodiment of the present disclosure, with a first conductive member, a second conductive member, and a sealing resin shown as transparent.

FIG. 20 is a partially enlarged view of FIG. 19.

FIG. 21 is a plan view of a semiconductor device according to a fifth embodiment of the present disclosure, with a sealing resin shown as transparent.

FIG. 22 is a sectional view taken along line XXII-XXII in FIG. 21.

FIG. 23 is a partially enlarged view of FIG. 21.

FIG. 24 is a sectional view taken along line XXIV-XXIV in FIG. 23.

### DETAILED DESCRIPTION OF EMBODIMENTS

Embodiments of the present disclosure are described with reference to the accompanying drawings.

### First Embodiment

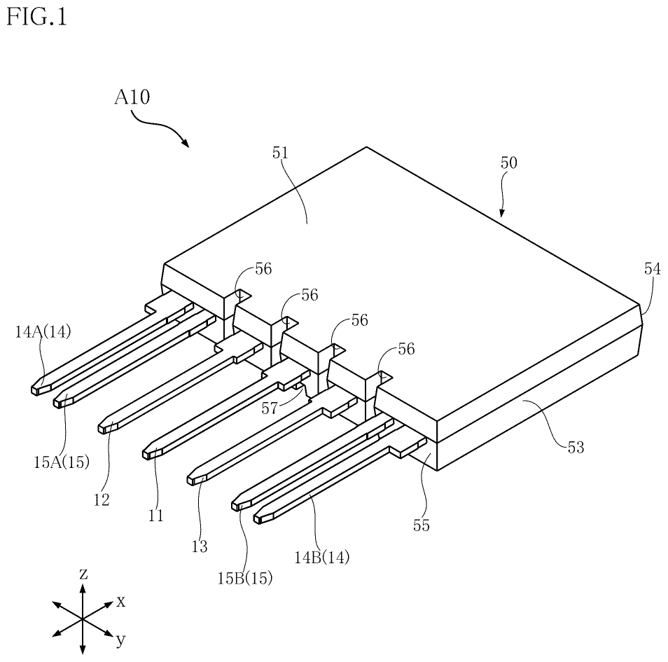

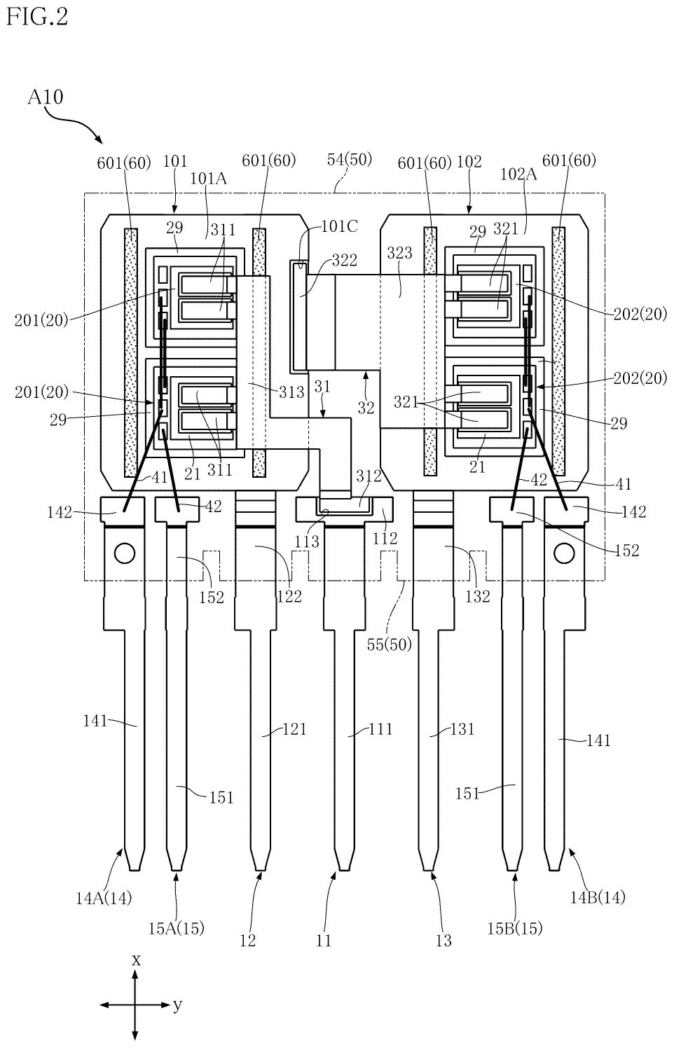

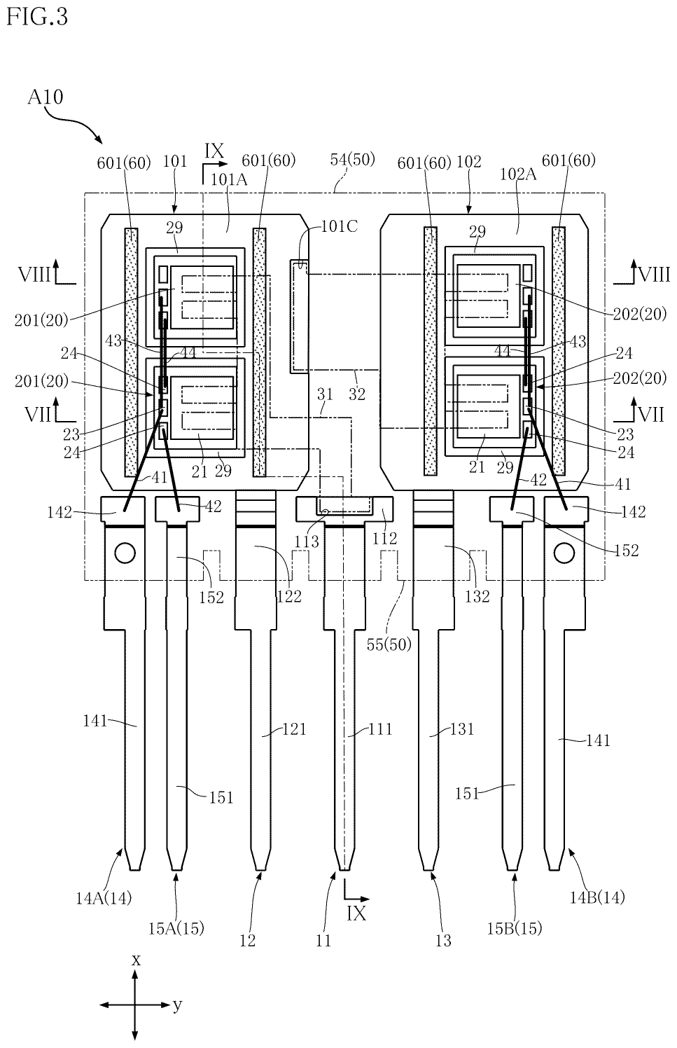

With reference to FIGS. 1 to 14, the following describes a semiconductor device A10 according to a first embodiment of the present disclosure. The semiconductor device A10 includes a first die pad 101, a second die pad 102, a first lead 11, a second lead 12, a third lead 13, two fourth leads 14, two fifth leads 15, a plurality of semiconductor elements 20, a first conductive member 31, a second conductive member 32, a sealing resin 50, and two reinforcement members 60. The semiconductor device A10 additionally includes two first wires 41, two second wires 42, two first relay wires 43, and two second relay wires 44. For convenience, FIGS. 2 and 3 show the sealing resin 50 as transparent. Similarly, FIG. 3 shows the first conductive member 31 and the second conductive member 32 as transparent. Also, FIG. 3 omits the illustration of a first conductive bonding layer 34, a second conductive bonding layer 35, a third conductive bonding layer 36, and a fourth conductive bonding layer 37. FIGS. 2 and 3 show the outline of the sealing resin 50 by imaginary lines (dash-double-dot lines). FIG. 3 shows the outlines of the first conductive member 31 and the second conductive member 32 by imaginary lines. FIG. 3 also shows the line IX-IX by a dot-dash line.

For the convenience in describing the semiconductor device A10, the direction of the normal to a later-described first obverse surface 101A of the first die pad 101 is referred to as a “first direction z”. A direction perpendicular to the first direction z is referred to as a “second direction x”. The direction perpendicular to the first direction z and the second direction x is referred to as a “third direction y”.

The semiconductor device A10 converts the DC power supply voltage that is applied to the first lead 11 and the third lead 13 into AC power using the semiconductor elements 20. The resulting AC power is output from the second lead 12 and supplied to a power supply target, such as a motor. The semiconductor device A10 is used for a power conversion circuit, such as an inverter.

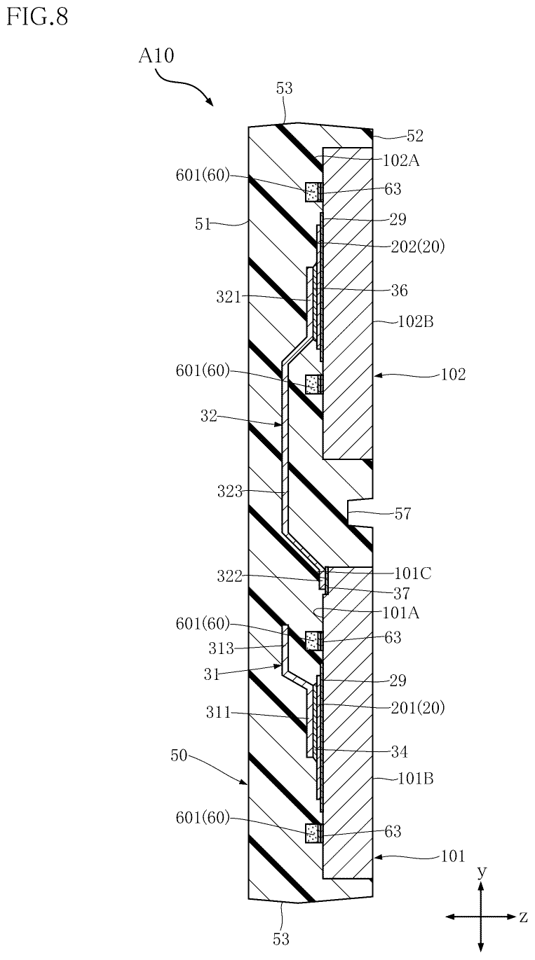

As shown in FIGS. 3 and 7, the first die pad 101 and the second die pad 102 are spaced apart from each other in the third direction y. The first die pad 101 and the second die pad 102 are obtained from the same lead frame, together with the first lead 11, the second lead 12, the third lead 13, the two fourth leads 14, and the two fifth leads 15. The lead frame contains copper (Cu) or a copper alloy.

As shown in FIGS. 7 and 8, the first die pad 101 has a first obverse surface 101A and a first reverse surface 101B facing away from each other in the first direction z. The second die pad 102 has a second obverse surface 102A and a second reverse surface 102B facing away from each other in the first direction z. The second obverse surface 102A faces the same side as the first obverse surface 101A in the first direction z. The first reverse surface 101B and the second reverse surface 102B are exposed from the sealing resin 50. As shown in FIG. 3, the first die pad 101 has a greater dimension in the second direction x than in the third direction y. The second die pad 102 has a greater dimension in the second direction x than in the third direction y.

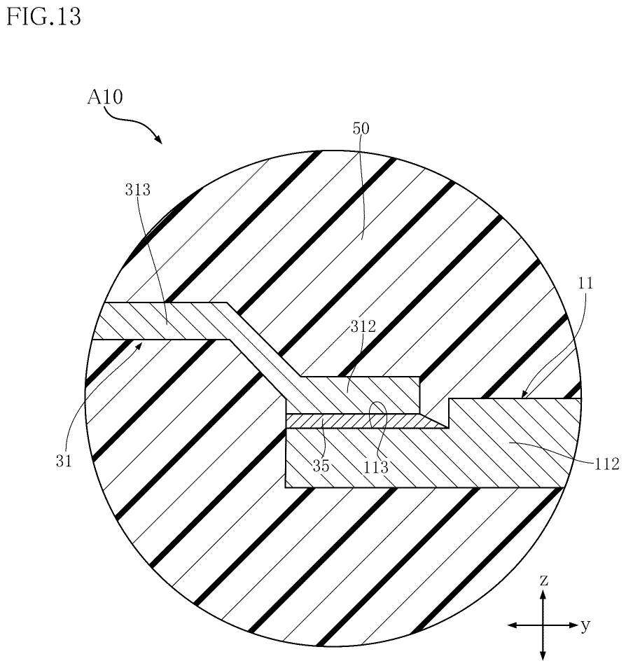

As shown in FIGS. 3 and 12, the first die pad 101 is formed with a first seat portion 101C. The first seat portion 101C is recessed from the first obverse surface 101A. That is, the first die pad 101 has a step between the first obverse surface 101A and the first seat portion 101C.

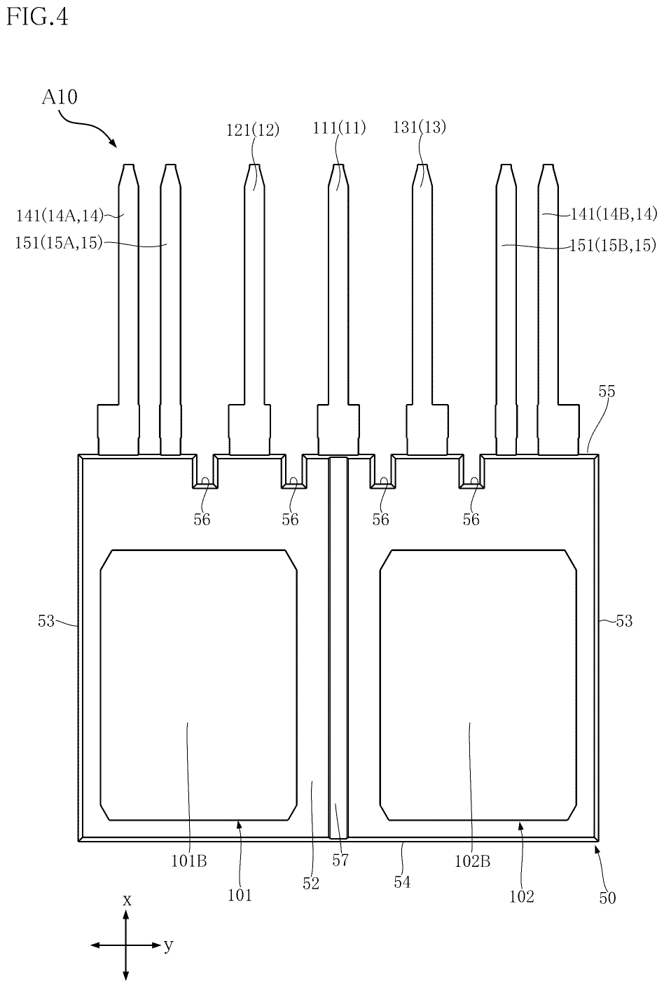

As shown in FIGS. 7 to 9, the sealing resin 50 covers the semiconductor elements 20, the first conductive member 31, and the second conductive member 32. The sealing resin 50 also covers a portion of each of the two die pads 10, the first lead 11, the second lead 12, the third lead 13, the two fourth leads 14, and the two fifth leads 15. The sealing resin 50 is electrically insulating. The sealing resin 50 is made of a material, including a black epoxy resin. As shown in FIG. 4, the sealing resin 50 has a greater dimension in the third direction y than in the second direction x. The sealing resin 50 has a top surface 51, a bottom surface 52, two first side surfaces 53, a second side surface 54, a third side surface 55, a plurality of recessed portions 56, and a trench 57.

As shown in FIGS. 7 and 8, the top surface 51 faces the same side as the first obverse surface 101A of the first die pad 101 in the first direction z. As shown in FIGS. 7 to 9, the bottom surface 52 faces away from the top surface 51 in the first direction z. As shown in FIG. 4, the first reverse surface 101B of the first die pad 101 and the second reverse surface 102B of the second die pad 102 are exposed at the bottom surface 52.

As shown in FIGS. 2, 4, and 5, the two first side surfaces 53 are spaced apart from each other in the third direction y. The first side surfaces 53 face in the third direction y and extend in the second direction x. The two first side surfaces 53 are connected to the top surface 51 and the bottom surface 52.

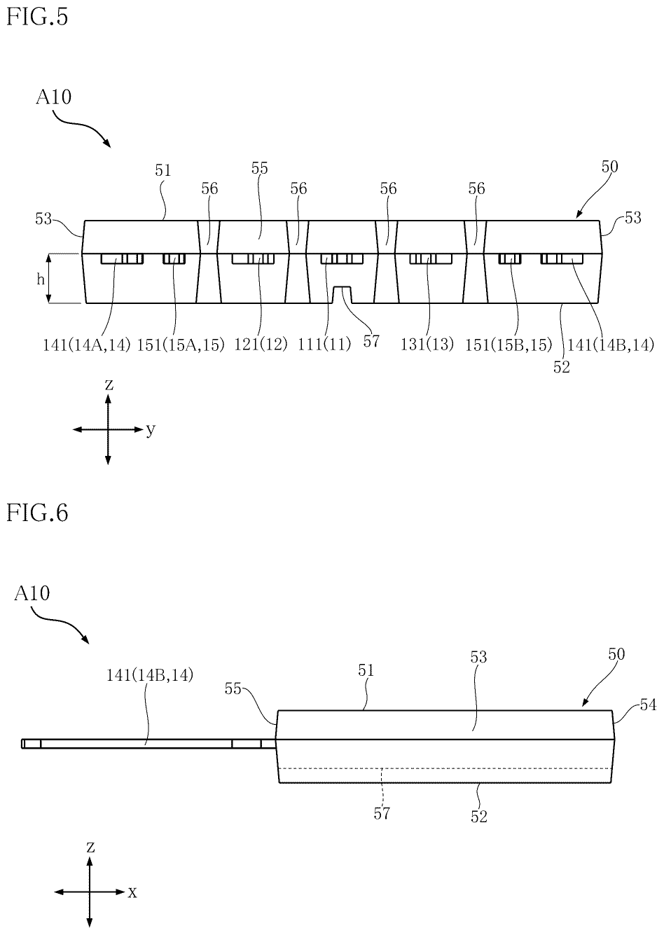

As shown in FIGS. 2, 4, and 6, the second side surface 54 and the third side surface 55 are spaced apart from each other in the second direction x. The second side surface 54 and the third side surface 55 face away from each other in the second direction x and extend in the third direction y. The second side surface 54 and the third side surface 55 are connected to the top surface 51 and the bottom surface 52. As shown in FIG. 5, the first lead 11, the second lead 12, the third lead 13, the two fourth leads 14, and the two fifth leads 15 protrude from the third side surface 55 to the outside.

As shown in FIGS. 1 and 4, the recessed portions 56 are each recessed from the third side surface 55 in the second direction x, and extends completely across the sealing resin 50 in the first direction z. The recessed portions 56 are arranged along the third direction y, with one located between the third lead 13 and a later-described second sense terminal 15B, one between the first lead 11 and the third lead 13, one between the first lead 11 and the second lead 12, and one between the second lead 12 and a later-described first sense terminal 15A.

As shown in FIGS. 4 and 5, the trench 57 is recessed from the bottom surface 52 in the first direction z and extends in the second direction x. Opposite ends of the trench 57 in the second direction x are connected to the second side surface 54 and the third side surface 55. As viewed in the first direction z, the trench 57 separates the first reverse surface 101B of the first die pad 101 and the second reverse surface 102B of the second die pad 102.

As shown in FIGS. 3, 7, and 8, the semiconductor elements 20 are each bonded to the first die pad 101 or the second die pad 102. The plurality of semiconductor elements 20 of the semiconductor device A10 include two first semiconductor elements 201 and two second semiconductor elements 202. The two first semiconductor elements 201 are bonded to the first obverse surface 101A of the first die pad 101 and are arranged along the second direction x. The two second semiconductor elements 202 are bonded to the second obverse surface 102A of the second die pad 102 and are arranged along the second direction x. The semiconductor elements 20 are metal-oxide-semiconductor field-effect transistors (MOSFETs), for example. In other examples, the semiconductor elements 20 may be switching elements, such as insulated gate bipolar transistors (IGBTs), or diodes. The description of the semiconductor device A10 assumes that the semiconductor elements 20 are n-channel vertical MOSFETs. The semiconductor elements 20 include a compound semiconductor substrate. The compound semiconductor substrate contains silicon carbide (SiC) in its composition. As shown in FIGS. 3, 10, and 11, each semiconductor element 20 includes a first electrode 21, a second electrode 22, a third electrode 23, and two fourth electrodes 24.

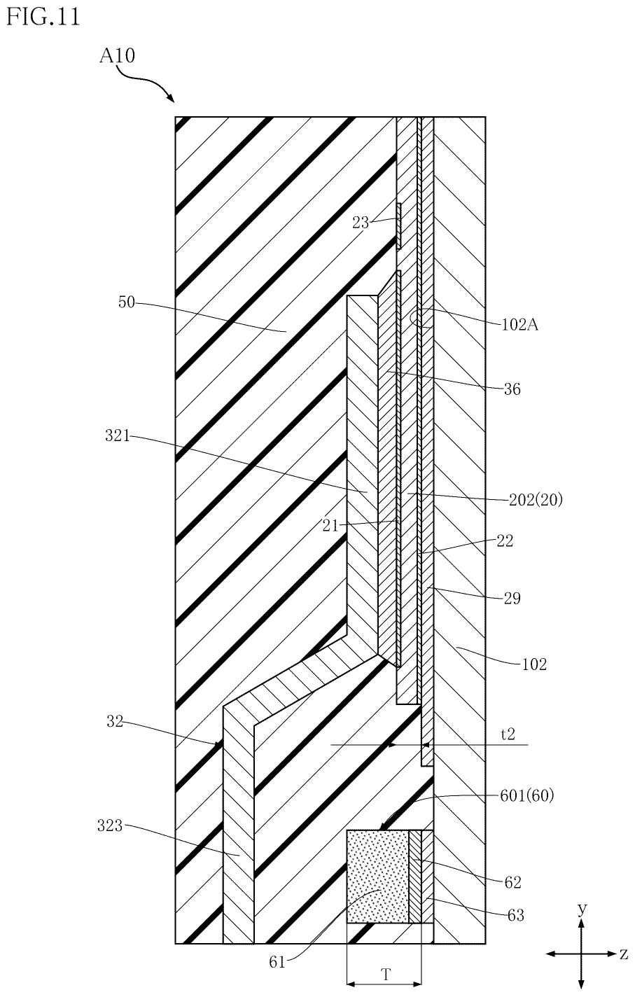

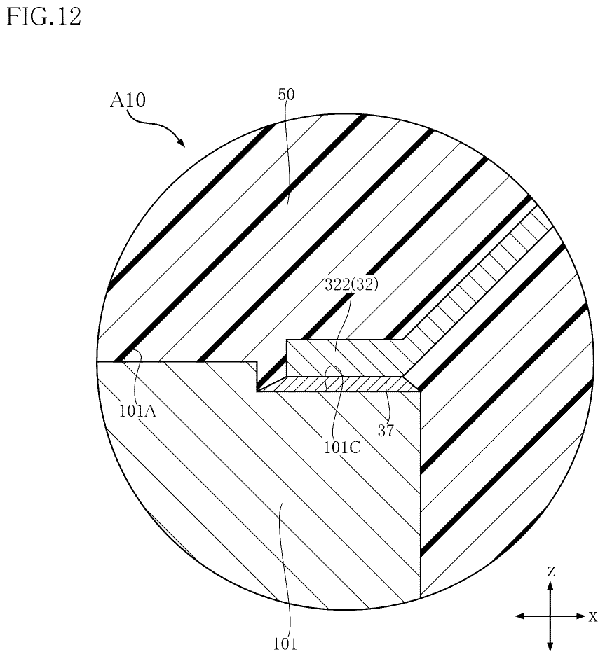

As shown in FIGS. 10 and 11, the first electrode 21 is located on the side that is opposite the side facing a corresponding one of the first obverse surface 101A and the second obverse surface 102A in the first direction z. The first electrode 21 conducts the current corresponding to the power having been converted by the semiconductor element 20. In other words, the first electrode 21 is the source electrode of the semiconductor element 20.

As shown in FIGS. 10 and 11, the second electrode 22 faces the corresponding one of the first obverse surface 101A and the second obverse surface 102A. The second electrode 22 conducts the current corresponding to the power to be converted by the semiconductor element 20. In other words, the second electrode 22 is the drain electrode of the semiconductor element 20.

As shown in FIGS. 10 and 11, the third electrode 23 is located on the same side as the first electrode 21 in the first direction z. The third electrode 23 receives a gate voltage to drive the semiconductor element 20. As viewed in the first direction z, the third electrode 23 has a smaller area than the first electrode 21.

As shown in FIG. 3, the two fourth electrodes 24 are located on the same side as the first electrode 21 in the first direction z. The two fourth electrodes 24 are located opposite to each other in the second direction x with respect to the third electrode 23. Each fourth electrode 24 receives the same voltage as that applied to the first electrode 21.

As shown in FIGS. 10 and 11, a conductive bonding layer 29 is provided between the first obverse surface 101A of the first die pad 101 and the two first semiconductor elements 201, and also between the second obverse surface 102A of the second die pad 102 and the two second semiconductor elements 202. The conductive bonding layers 29 is solder, for example. Alternatively, the conductive bonding layers 29 may be sintered metal. The conductive bonding layer 29 electrically bonds the first obverse surface 101A and the second electrode 22 of each first semiconductor element 201. This electrically connects the second electrode 22 of each first semiconductor element 201 to the first die pad 101. Also, the conductive bonding layer 29 electrically bonds the second obverse surface 102A and the second electrode 22 of each second semiconductor element 202. This electrically connects the second electrode 22 of each second semiconductor element 202 to the second die pad 102.

As shown in FIGS. 2 and 3, the first lead 11 is located on the side opposite the second side surface 54 of the sealing resin 50 in the second direction x, with respect to the two die pads 10. The first lead 11 is spaced apart from the two die pads 10. The first lead 11 is electrically connected to the first electrodes 21 of the two first semiconductor elements 201. The first lead 11 is an N terminal (negative terminal) to which the DC power supply voltage to be converted is applied.

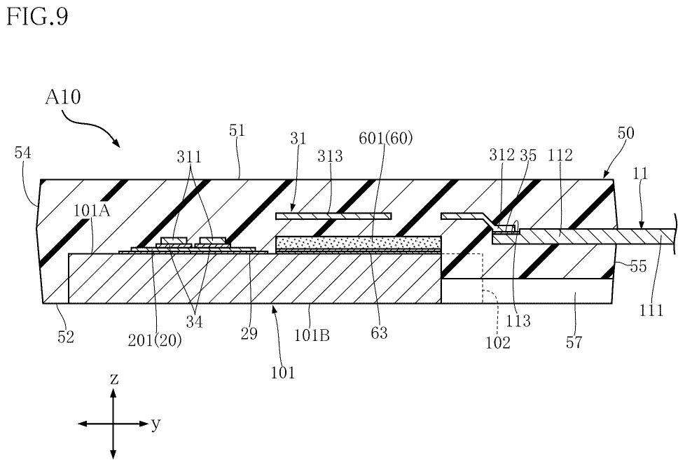

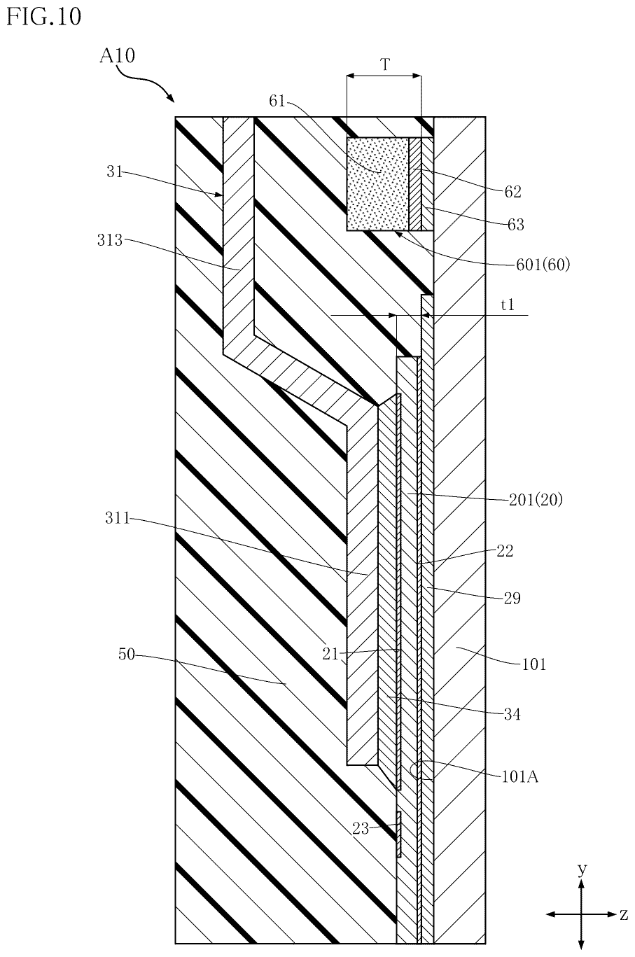

As shown in FIGS. 3 and 9, the first lead 11 includes a mounting portion 111 and a covered portion 112. The mounting portion 111 protrudes from the third side surface 55 of the sealing resin 50 to the outside. The mounting portion 111 extends in the second direction x. The covered portion 112 is connected to the mounting portion 111. The covered portion 112 is covered with the sealing resin 50.

As shown in FIGS. 3 and 13, the covered portion 112 of the first lead 11 is formed with a second seat portion 113. The second seat portion 113 is recessed in the first direction z from the side in the first direction z where a later-described first intermediate portion 313 of the first conductive member 31 is present.

As shown in FIG. 3, the second lead 12 is connected to the first die pad 101. Hence, the second lead 12 is electrically connected to the second electrodes 22 of the two first semiconductor elements 201 via the first die pad 101. The second lead 12 outputs the AC power having been converted by the semiconductor elements 20. The second lead 12 is located on the side opposite the third lead 13 with respect to the first lead 11 and is next to the first lead 11. The second lead 12 includes a mounting portion 121 and a covered portion 122. The mounting portion 121 protrudes from the third side surface 55 of the sealing resin 50 to the outside. The mounting portion 121 extends in the second direction x. The covered portion 122 connects the mounting portion 121 and the first die pad 101. The covered portion 122 is covered with the sealing resin 50. The covered portion 122 is bent toward the first obverse surface 101A of the first die pad 101 in the first direction z.

As shown in FIG. 3, the third lead 13 is connected to the second die pad 102. Hence, the third lead 13 is electrically connected to the second electrodes 22 of the two second semiconductor elements 202 via the second die pad 102. The third lead 13 is a P terminal (positive terminal) to which the DC power supply voltage to be converted is applied. The third lead 13 is located on the side opposite the second lead 12 with respect to the first lead 11 and is next to the first lead 11. The third lead 13 includes a mounting portion 131 and a covered portion 132. The mounting portion 131 protrudes from the third side surface 55 of the sealing resin 50 to the outside. The mounting portion 131 extends in the second direction x. The covered portion 132 connects the mounting portion 131 and the second die pad 102. The covered portion 132 is covered with the sealing resin 50. The covered portion 132 is bent toward the second obverse surface 102A of the second die pad 102 in the first direction z.

As shown in FIGS. 2 and 3, the two fourth leads 14 are located on the side opposite the second side surface 54 of the sealing resin 50 in the second direction x, with respect to the two die pads 10. As shown in FIG. 3, the two fourth leads 14 extend in the second direction x. The two fourth leads 14 are located to have the first lead 11, the second lead 12, the third lead 13, and the two fifth leads 15 between them in the third direction y. The two fourth leads 14 include a first gate terminal 14A and a second gate terminal 14B.

As shown in FIG. 3, each fourth lead 14 includes a mounting portion 141 and a covered portion 142. The mounting portion 141 protrudes from the third side surface 55 of the sealing resin 50 to the outside. The mounting portion 141 extends in the second direction x. The covered portion 142 is connected to the mounting portion 141. The covered portion 142 is covered with the sealing resin 50.

As shown in FIG. 3, the first gate terminal 14A is closer to the first die pad 101 than to the second die pad 102. The first gate terminal 14A is electrically connected to the third electrode 23 of each first semiconductor element 201. The first gate terminal 14A receives a gate voltage for driving the two first semiconductor elements 201.

As shown in FIG. 3, the second gate terminal 14B is closer to the second die pad 102 than to the first die pad 101. The second gate terminal 14B is electrically connected to the third electrode 23 of each second semiconductor element 202. The second gate terminal 14B receives a gate voltage for driving the two second semiconductor element 202.

As shown in FIGS. 2 and 3, the two fifth leads 15 are located on the side opposite the second side surface 54 of the sealing resin 50 in the second direction x, with respect to the two die pads 10. As shown in FIG. 3, the two fifth leads 15 extend in the second direction x. The two fifth leads 15 are located to have the first lead 11, the second lead 12, and the third lead 13 between them in the third direction y. The two fifth leads 15 include a first sense terminal 15A and a second sense terminal 15B.

As shown in FIG. 3, each fifth lead 15 includes a mounting portion 151 and a covered portion 152. The mounting portion 151 protrudes from the third side surface 55 of the sealing resin 50 to the outside. The mounting portion 151 extends in the second direction x. The covered portion 152 is connected to the mounting portion 151. The covered portion 152 is covered with the sealing resin 50.

As shown in FIGS. 2 and 3, the first sense terminal 15A is located between the second lead 12 and the first gate terminal 14A. The first sense terminal 15A is electrically connected to the two fourth electrodes 24 of each first semiconductor element 201. The first sense terminal 15A receives the same voltage as that applied to the first electrode 21 of each first semiconductor element 201.

As shown in FIGS. 2 and 3, the second sense terminal 15B is located between the third lead 13 and the second gate terminal 14B. The second sense terminal 15B is electrically connected to the two fourth electrodes 24 of each second semiconductor element 202. The second sense terminal 15B receives the same voltage as that applied to the first electrode 21 of each second semiconductor element 202.

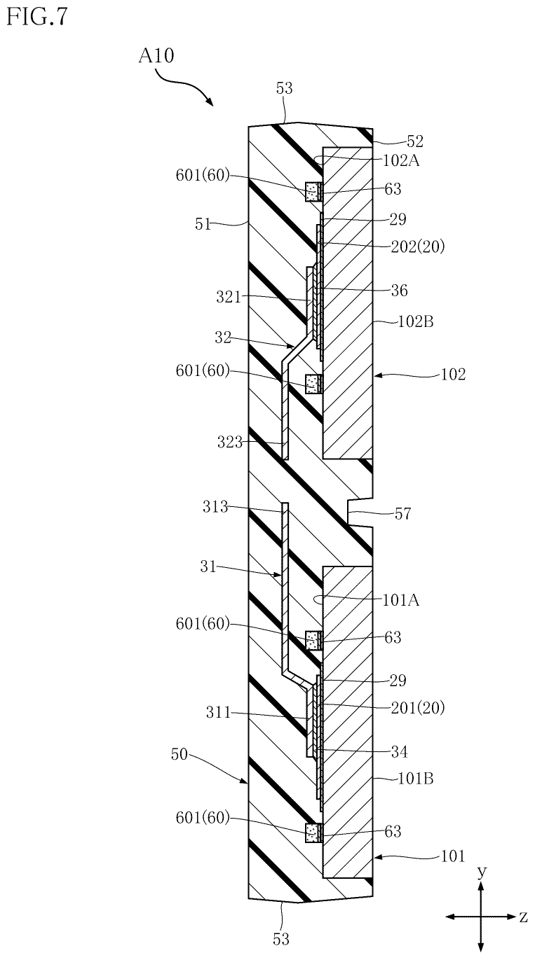

As shown in FIG. 5, the mounting portion 111 of the first lead 11, the mounting portion 121 of the second lead 12, and the mounting portion 131 of the third lead 13 are all at the same height h. As shown in FIG. 6, the mounting portion 141 of each fourth lead 14 overlaps with each of the mounting portion 111 of the first lead 11, the mounting portion 121 of the second lead 12, and the mounting portion 131 of the third lead 13 as viewed in the third direction y.

As shown in FIGS. 2 and 9, the first conductive member 31 is electrically bonded to the first electrodes 21 of the two first semiconductor elements 201 and the second seat portion 113 of the first lead 11. This electrically connects the first lead 11 to the first electrode 21 of each first semiconductor element 201. The first conductive member 31 contains copper or a copper alloy. The first conductive member 31 is a metal clip. The first conductive member 31 includes two first bonding portions 311, a second bonding portion 312, and a first intermediate portion 313.

As shown in FIGS. 3 and 10, the two first bonding portions 311 are each electrically bonded to the first electrode 21 of one of the two first semiconductor elements 201. The two first bonding portions 311 each have bifurcated ends that are spaced apart from each other in the second direction x. As shown in FIG. 3, the two first bonding portions 311 are spaced apart from each other in the second direction x.

As shown in FIGS. 3 and 13, the second bonding portion 312 is electrically bonded to the second seat portion 113 of the first lead 11. The second bonding portion 312 extends in the third direction y. At least a portion of the second bonding portion 312 is received within the second seat portion 113.

As shown in FIGS. 7 to 10, the semiconductor device A10 additionally includes a first conductive bonding layer 34. The first conductive bonding layer 34 electrically bonds the first electrodes 21 of the two first semiconductor elements 201 and the two first bonding portions 311. The first conductive bonding layer 34 is solder, for example. Alternatively, the first conductive bonding layer 34 may be sintered metal.

As shown in FIGS. 9 and 13, the semiconductor device A10 additionally includes a second conductive bonding layer 35. The second conductive bonding layer 35 electrically bonds the second seat portion 113 of the first lead 11 and the second bonding portion 312. The second conductive bonding layer 35 is solder, for example. Alternatively, the second conductive bonding layer 35 may be sintered metal.

As shown in FIGS. 3 and 8, the second conductive member 32 is electrically bonded to the first electrodes 21 of the two second semiconductor elements 202 and the first seat portion 101C of the first die pad 101. This electrically connects the first electrode 21 of each second semiconductor element 202 to the first die pad 101 and the second electrode 22 of each first semiconductor element 201. The second conductive member 32 contains copper or a copper alloy. The second conductive member 32 is a metal clip. The second conductive member 32 includes two third bonding portions 321, a fourth bonding portion 322, and a second intermediate portion 323.

As shown in FIGS. 3 and 11, the two third bonding portions 321 are each electrically bonded to the first electrode 21 of one of the two second semiconductor elements 202. The two third bonding portions 321 each have bifurcated ends that are spaced apart from each other in the second direction x. As shown in FIG. 3, the two third bonding portions 321 are spaced apart from each other in the second direction x.

As shown in FIGS. 3 and 12, the fourth bonding portion 322 is electrically bonded to the first seat portion 101C of the first die pad 101. The fourth bonding portion 322 extends in the second direction x. At least a portion of the fourth bonding portion 322 is received within the first seat portion 101C.

As shown in FIG. 3, the second intermediate portion 323 connects the two third bonding portions 321 and the fourth bonding portion 322. The second intermediate portion 323 extends across the gap between the first die pad 101 and the second die pad 102.

As shown in FIGS. 7, 8, and 11, the semiconductor device A10 additionally includes a third conductive bonding layer 36. The third conductive bonding layer 36 electrically bonds the first electrodes 21 of the two second semiconductor elements 202 and the two third bonding portions 321. The third conductive bonding layer 36 is solder, for example. Alternatively, the third conductive bonding layer 36 may be sintered metal.

As shown in FIGS. 8 and 12, the semiconductor device A10 additionally includes a fourth conductive bonding layer 37. The fourth conductive bonding layer 37 electrically bonds the first seat portion 101C of the first die pad 101 and the fourth bonding portion 322. The fourth conductive bonding layer 37 is solder, for example. Alternatively, the fourth conductive bonding layer 37 may be sintered metal.

As shown in FIG. 3, one of the two first wires 41 is electrically bonded to the covered portion 142 of the first gate terminal 14A and to the third electrode 23 of the first semiconductor elements 201 that is closer to the first gate terminal 14A. Also as shown in FIG. 3, the other first wire 41 is electrically bonded to the covered portion 142 of the second gate terminal 14B and to the third electrode 23 of the second semiconductor element 202 that is closer to the second gate terminal 14B.

As shown in FIG. 3, one of the two first relay wires 43 is electrically bonded to the third electrode 23 of one first semiconductor element 201 and to the third electrode 23 of the other first semiconductor element 201. Also as shown in FIG. 3, the other first relay wire 43 is electrically bonded to the third electrode 23 of one second semiconductor element 202 and to the third electrode 23 of the other second semiconductor element 202. With the two first wires 41 and the two first relay wires 43, the first gate terminal 14A is electrically connected to the third electrodes 23 of the two first semiconductor elements 201. Also, the second gate terminal 14B is electrically connected to the third electrodes 23 of the two second semiconductor elements 202.

As shown in FIG. 3, one of the two second wires 42 is electrically bonded to the covered portion 152 of the first sense terminal 15A and to a fourth electrode 24 of the first semiconductor element 201 that is closer to the first sense terminal 15A. Also as show in FIG. 3, the other second wire 42 is electrically bonded to the covered portion 152 of the second sense terminal 15B and to a fourth electrode 24 of the second semiconductor element 202 that is closer to the second sense terminal 15B.

As shown in FIG. 3, one of the two second relay wires 44 is electrically bonded to a fourth electrode 24 of one first semiconductor element 201 and to a fourth electrode 24 of the other first semiconductor element 201. Also as shown in FIG. 3, the other second relay wire 44 is electrically bonded to a fourth electrode 24 of one second semiconductor element and to a fourth electrode 24 of the other second semiconductor element 202. With the two second wires 42 and the two second relay wires 44, the first sense terminal 15A is electrically connected to the two fourth electrodes 24 of each first semiconductor element 201. Also, the second sense terminal 15B is electrically connected to the two fourth electrodes 24 of each second semiconductor element 202.

As shown in FIGS. 3, 7, and 8, the two reinforcement members 60 are each bonded to the first obverse surface 101A of the first die pad 101 or the second obverse surface 102A of the second die pad 102. The two reinforcement members 60 are covered with the sealing resin 50. The two reinforcement members 60 each have a linear expansion coefficient smaller than that of the sealing resin 50. Preferably, the linear expansion coefficient of each reinforcement member 60 is the same or close to that of each semiconductor element 20. In the semiconductor device A10, the two reinforcement members 60 are identical or similar to each other in configuration. Thus, the following description of the semiconductor device A10 focuses solely on the reinforcement member 60 bonded to the first obverse surface 101A, among the two reinforcement members 60.

As shown in FIGS. 7 and 8, the reinforcement member 60 is bonded to the first obverse surface 101A of the first die pad 101, which means that the reinforcement member 60 is located on the same side as the two first semiconductor elements 201 in the first direction z with respect to the first die pad 101. As shown in FIG. 3, the reinforcement member 60 includes two first reinforcement members 601. The two first reinforcement members 601 are located opposite to each other in the third direction y with respect to the two first semiconductor elements 201. The two first reinforcement members 601 each extend in the second direction x.

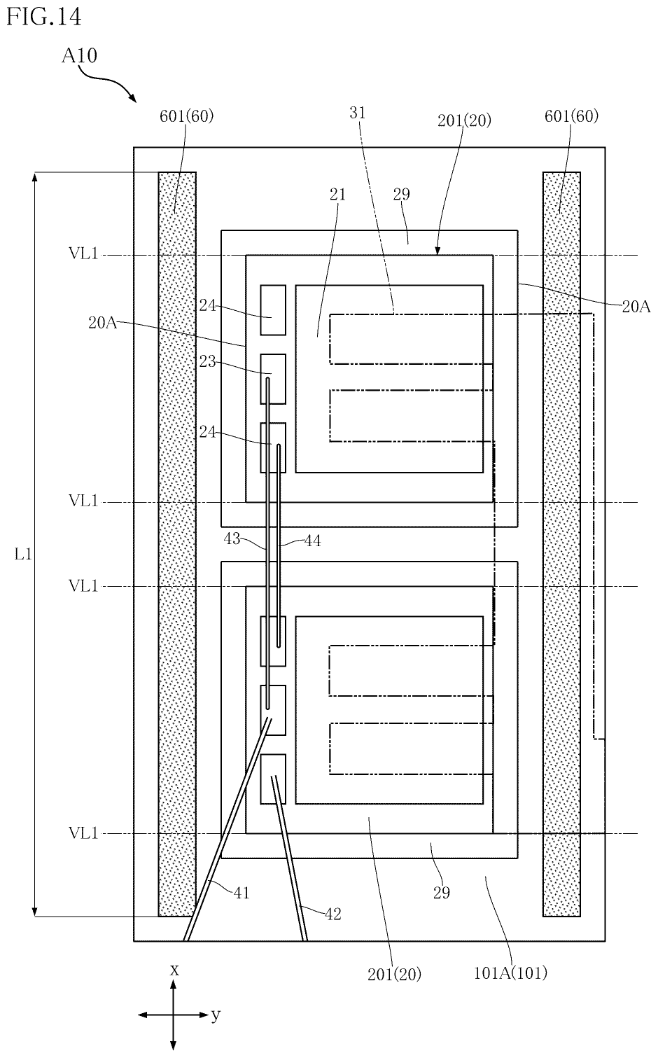

As shown in FIG. 14, each first semiconductor element 201 has two first edges 20A as viewed in the first direction z. The two first edges 20A are spaced apart from each other in the third direction y. The two first edges 20A each extend in the second direction x. Each first reinforcement member 601 has a dimension L1 in the second direction x that is greater than the dimension of each first edge 20A. When two first imaginary lines VL1 extend in the third direction y and pass through the ends of the respective first edges 20A, each of these first imaginary lines VL1 intersects the two first reinforcement members 601 as viewed in the first direction z.

As shown in FIG. 10, the reinforcement member 60 has a dimension T in the first direction z, and each first semiconductor element 201 has a dimension t1 in the first direction z, where T is greater than t1. Additionally, as shown in FIG. 11, the dimension T is greater than a dimension t2 of each second semiconductor element 202 in the first direction z.

As shown in FIGS. 10 and 11, the reinforcement member 60 includes an insulating layer 61 and a first metal layer 62. The first metal layer 62 is stacked on the insulating layer 61. A portion of the sealing resin 50 is located between the insulating layer 61 and the first conductive member 31 in the first direction z. The insulating layer 61 has a thermal conductivity that is higher than that of the sealing resin 50. Examples of the insulating layer 61 include ceramic materials containing either aluminum oxide (Al₂O₃) or aluminum (AlN), and carbon fiber reinforced plastic (CFRP). The first metal layer 62 contains copper or silver (Ag), for example. The first metal layer 62 may be formed by depositing a thin film of metal on the insulating layer 61 by sputtering. The first metal layer 62 is bonded to the first obverse surface 101A of the first die pad 101 via a first bonding layer 63. The first bonding layer 63 is solder, for example.

In some cases, the reinforcement member 60 is made of a metal. Examples of the metal include iron (Fe), an iron-nickel (Ni) alloy, and stainless steel (SUS). In such a case, the reinforcement member 60 is bonded to the first obverse surface 101A of the first die pad 101 via a first bonding layer 63.

The following describes operation and effect of the semiconductor device A10.

The semiconductor device A10 includes a first die pad 101, a first semiconductor element 201 bonded to the first die pad 101, a sealing resin 50 covering the first semiconductor element 201, and a reinforcement member 60 bonded to the first die pad 101. The linear expansion coefficient of the reinforcement member 60 is smaller than that of the sealing resin 50. With this configuration, when the heat from the first semiconductor element 201 causes the first die pad 101 to thermally expand, the reinforcement member 60 restricts the expansion. This serves to reduce the thermal strain imposed on the first die pad 101. This consequently reduces the thermal stress occurring at the interface between the first die pad 101 and the sealing resin 50 and thus reduces the thermal stress occurring at the interface between the first semiconductor element 201 and the sealing resin 50. This configuration thus enables the semiconductor device A10 to reduce the thermal stress occurring at the interface between the first semiconductor element 201 and the sealing resin 50.

The reinforcement member 60 is located on the same side as the first semiconductor element 201 with respect to the first die pad 101 in the first direction z. This configuration allows the reinforcement member 60 to be included without the need to increase the dimensions of the semiconductor device A10.

The reinforcement member 60 includes a first reinforcement member 601 extending in the second direction x. The dimension L1 of the first reinforcement member 601 in the second direction x is greater than the dimension of the first edge 20A of the first semiconductor element 201. Note that the first die pad 101 has a greater dimension in the second direction x than in the third direction y and thus experiences greater thermal strain in the second direction x than in the third direction y. Advantageously. the configuration of the present embodiment reduces the thermal strain imposed on the first die pad 101 in the second direction x and thus efficiently reduces the thermal stress occurring at the interface between the first semiconductor element 201 and the sealing resin 50.

Additionally, two first imaginary lines VL1 that extend in the third direction y and pass through the ends of the first edge 20A of the first semiconductor element 201 each intersect the first reinforcement member 601 as viewed in the first direction z. This configuration reduces the thermal stress occurring at the bonding interface between the first die pad 101 and the first semiconductor element 201.

The dimension T of the reinforcement member 60 in the first direction z is greater than the dimension t1 of the first semiconductor element 201 in the first direction z. This configuration allows the thermal stress to be concentrated more at the bonding interface between the first die pad 101 and the reinforcement member 60 than at the bonding interface between the first die pad 101 and the first semiconductor element 201. This efficiently reduces the thermal stress occurring at the bonding interface between the first die pad 101 and the first semiconductor element 201.

The first die pad 101 is provided with a first seat portion 101C that is recessed from the first obverse surface 101A. A portion of the second conductive member 32 is received within the first seat portion 101C. With this configuration, the first seat portion 101C restricts rotation of the second conductive member 32 around the first direction z during the process of electrically bonding the second conductive member 32 to the second semiconductor element 202 and the first die pad 101. This prevents misalignment of the second conductive member 32 relative to the second semiconductor element 202.

The first lead 11 is provided with a second seat portion 113 that is recessed in the first direction z from the side where the first intermediate portion 313 of the first conductive member 31 is located in the first direction z. A second bonding portion 312 of the first conductive member 31 has a portion received within the second seat portion 113. With this configuration, the second seat portion 113 restricts rotation of the first conductive member 31 around the first direction z during the process of electrically bonding the first conductive member 31 to the first semiconductor element 201 and the first lead 11. This prevents misalignment of the first conductive member 31 relative to the first semiconductor element 201.

The second lead 12 is connected to the first die pad 101. The third lead 13 is connected to the second die pad 102. This configuration allows the first die pad 101 and the second die pad 102 to serve as conduction paths of the semiconductor device A10 without the need to increase the dimensions of the semiconductor device A10.

The first reverse surface 101B of the first die pad 101 and the second reverse surface 102B of the second die pad 102 are exposed from the sealing resin 50. This configuration improves the heat dissipation of the semiconductor device A10.

The sealing resin 50 has a plurality of recessed portions 56 each recessed from the third side surface 55 in the second direction x. This configuration provides the sealing resin 50 with a longer creepage distance between adjacent leads among the first lead 11, the second lead 12, and the third lead 13. This consequently improves the dielectric strength of the semiconductor device A10.

The sealing resin 50 has a bottom surface 52 formed with a trench 57. As viewed in the first direction z, the trench 57 separates the first reverse surface 101B of the first die pad 101 and the second reverse surface 102B of the second die pad 102. This configuration provides the sealing resin 50 with a longer creepage distance between the first die pad 101 and the second die pad 102. This further improves the dielectric strength of the semiconductor device A10. This also disperses the thermal strain on the sealing resin 50 in the third direction y, preventing thermal strain from concentrating on the first side surfaces 53 of the sealing resin 50.

### Second Embodiment

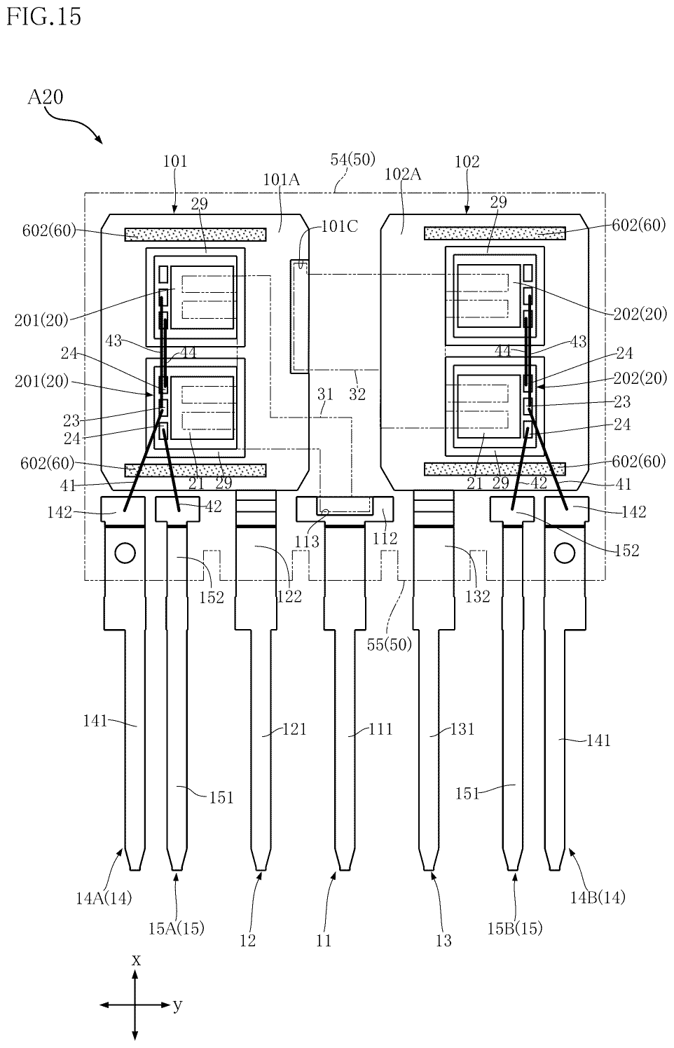

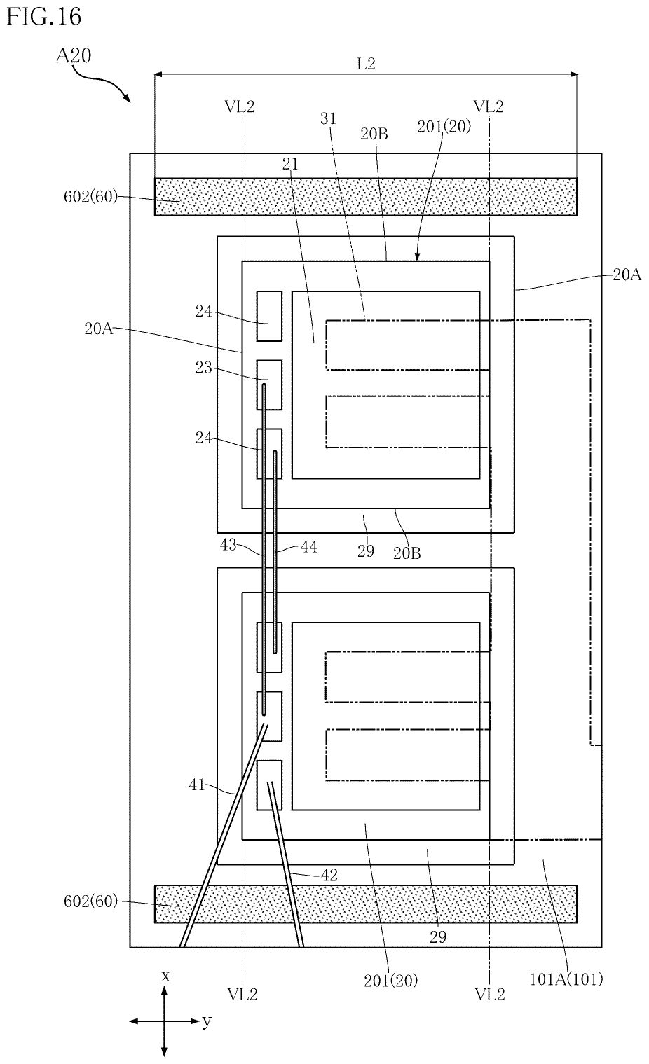

With reference to FIGS. 15 and 16, the following describes a semiconductor device A20 according to a second embodiment of the present disclosure. In these figures, elements identical or similar to those of the semiconductor device A10 described above are indicated by the same reference numerals, and redundant descriptions are omitted. For convenience, FIG. 15 shows a first conductive member 31, a second conductive member 32, and a sealing resin 50 as transparent. FIG. 15 shows the outlines of the first conductive member 31, the second conductive member 32, and the sealing resin 50 by imaginary lines.

The semiconductor device A20 differs from the semiconductor device A10 in the configuration of the two reinforcement members 60. In the semiconductor device A20, the two reinforcement members 60 are identical or similar to each other in configuration. Thus, the following description of the semiconductor device A20 focuses solely on the reinforcement member 60 that is bonded to the first obverse surface 101A of the first die pad 101.

As shown in FIG. 15, the reinforcement member 60 includes two second reinforcement members 602 instead of the two first reinforcement members 601. The two second reinforcement members 602 are located opposite to each other in the second direction x with respect to the two first semiconductor elements 201. The two second reinforcement members 602 each extend in the third direction y.

As shown in FIG. 16, each first semiconductor element 201 has two second edges 20B as viewed in the first direction z. The two second edges 20B are spaced apart from each other in the second direction x. The two second edges 20B each extend in the third direction y. Each second reinforcement member 602 has a dimension L2 in the third direction y that is greater than the dimension of each second edge 20B. When two second imaginary lines VL2 extend in the second direction x and pass through the ends of the respective second edges 20B, each of these second imaginary lines VL2 intersects the two second reinforcement members 602 as viewed in the first direction z.

The following describes operation and effect of the semiconductor device A20.

The semiconductor device A20 includes a first die pad 101, a first semiconductor element 201 bonded to the first die pad 101, a sealing resin 50 covering the first semiconductor element 201, and a reinforcement member 60 bonded to the first die pad 101. The linear expansion coefficient of the reinforcement member 60 is smaller than that of the sealing resin 50. This configuration thus enables the semiconductor device A20 to reduce the thermal stress occurring at the interface between the first semiconductor element 201 and the sealing resin 50. Additionally, the semiconductor device A20 has a configuration in common with the semiconductor device A10, thereby achieving the same effect as the semiconductor device A10.

The reinforcement member 60 of the semiconductor device A20 includes a second reinforcement member 602 extending in the third direction y. The dimension L2 of the second reinforcement member 602 in the third direction y is greater than the dimension of the second edge 20B of the first semiconductor element 201. Note that the sealing resin 50 has a greater dimension in the third direction y than in the second direction x and thus experiences greater thermal strain in the third direction y than in the second direction x due to the thermal stress occurring at the interface between the first die pad 101 and the sealing resin 50. Advantageously. the configuration of the present embodiment reduces the thermal strain on the first die pad 101 in the third direction y and thus efficiently reduces the thermal strain on the sealing resin 50.

### Third Embodiment

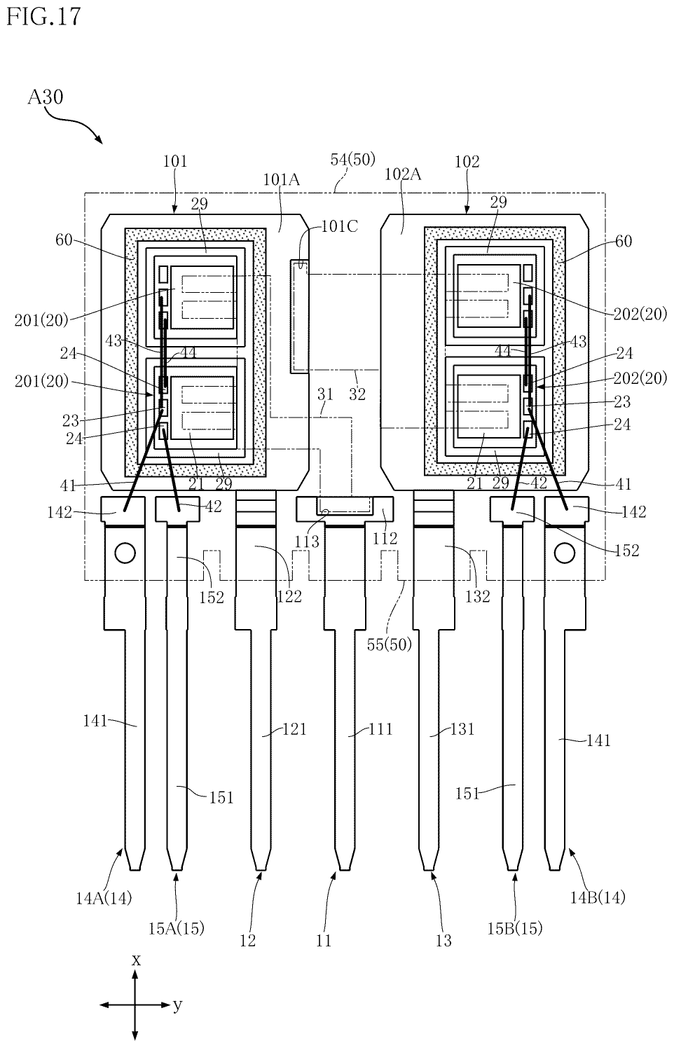

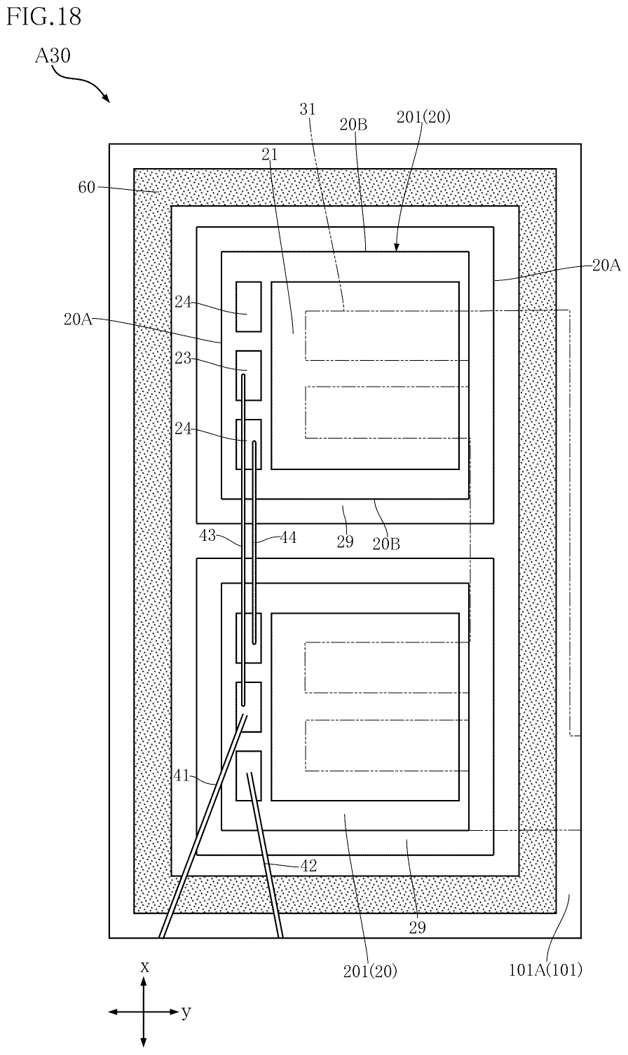

With reference to FIGS. 17 and 18, the following describes a semiconductor device A30 according to a third embodiment of the present disclosure. In these figures, elements identical or similar to those of the semiconductor devices A10 and A20 described above are indicated by the same reference numerals, and redundant descriptions are omitted. For convenience, FIG. 17 shows a first conductive member 31, a second conductive member 32, and a sealing resin 50 as transparent. FIG. 17 shows the outlines of the first conductive member 31, the second conductive member 32, and the sealing resin 50 by imaginary lines.

The semiconductor device A30 differs from the semiconductor device A10 in the configuration of the two reinforcement members 60. In the semiconductor device A30, the two reinforcement members 60 are identical or similar to each other in configuration. Thus, the following description of the semiconductor device A30 focuses solely on the reinforcement member 60 that is bonded to the first obverse surface 101A of the first die pad 101.

As shown in FIGS. 17 and 18, each reinforcement member 60 is a single member and does not include the two first reinforcement members 601 or the two second reinforcement members 602. The reinforcement member 60 surrounds the two first semiconductor elements 201 as viewed in the first direction z.

The following describes operation and effect of the semiconductor device A30.

The semiconductor device A30 includes a first die pad 101, a first semiconductor element 201 bonded to the first die pad 101, a sealing resin 50 covering the first semiconductor element 201, and a reinforcement member 60 bonded to the first die pad 101. The linear expansion coefficient of the reinforcement member 60 is smaller than that of the sealing resin 50. This configuration thus enables the semiconductor device A30 to reduce the thermal stress occurring at the interface between the first semiconductor element 201 and the sealing resin 50. Additionally, the semiconductor device A30 has a configuration in common with the semiconductor device A10, thereby achieving the same effect as the semiconductor device A10.

The reinforcement member 60 of the semiconductor device A30 surrounds the first semiconductor element 201 as viewed in the first direction z. This configuration reduces the thermal strain imposed on the first die pad 101 in both the second direction x and the third direction y. This prevents the first die pad 101 from experiencing an uneven distribution of thermal strain. In addition, the thermal strain on the first die pad 101 is reduced in the area around the first semiconductor element 201, thereby more efficiently reducing the thermal stress at the bonding interface between the first die pad 101 and the first semiconductor element 201.

### Fourth Embodiment

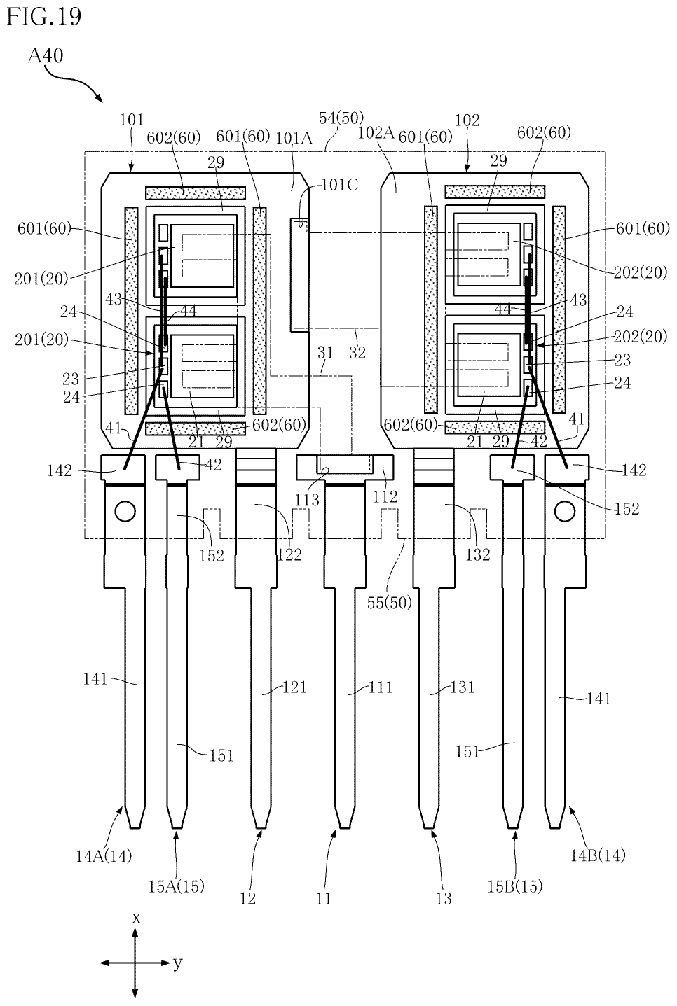

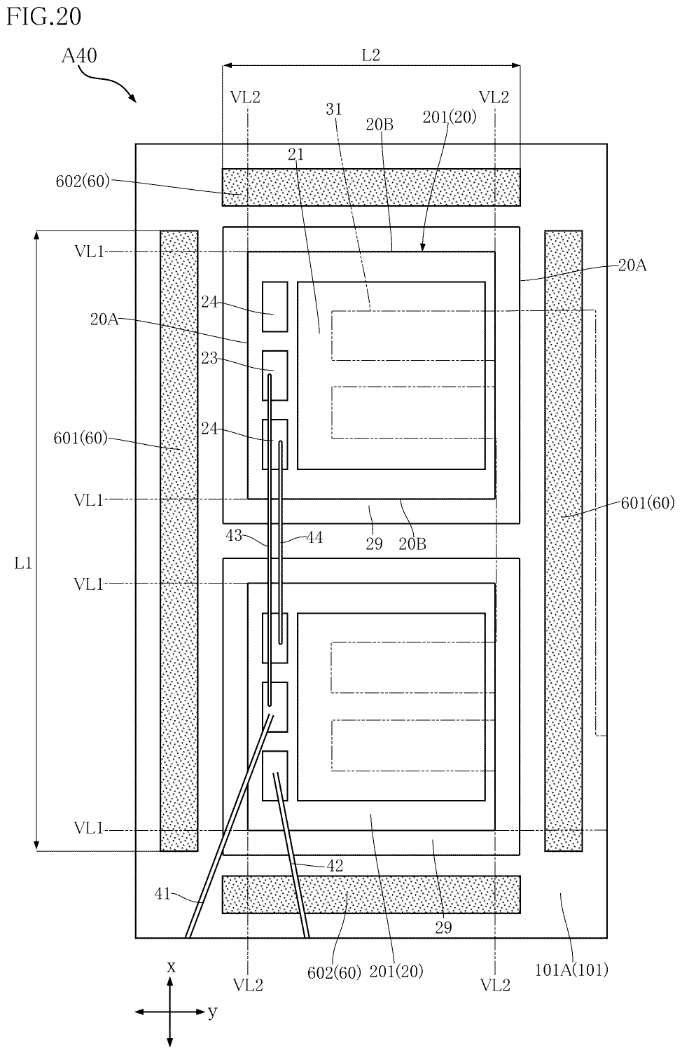

With reference to FIGS. 19 and 20, the following describes a semiconductor device A40 according to a fourth embodiment of the present disclosure. In these figures, elements identical or similar to those of the semiconductor devices A10 and A20 described above are indicated by the same reference numerals, and redundant descriptions are omitted. For convenience, FIG. 19 shows a first conductive member 31, a second conductive member 32, and a sealing resin 50 as transparent. FIG. 19 shows the outlines of the first conductive member 31, the second conductive member 32, and the sealing resin 50 by imaginary lines.

The semiconductor device A40 differs from the semiconductor device A10 in the configuration of the two reinforcement members 60. In the semiconductor device A40, the two reinforcement members 60 are identical or similar to each other in configuration. Thus, the following description of the semiconductor device A40 focuses solely on the reinforcement member 60 that is bonded to the first obverse surface 101A of the first die pad 101.

As shown in FIG. 19, the reinforcement member 60 includes two first reinforcement members 601 and two second reinforcement members 602. Each first reinforcement member 601 is spaced apart from both the two second reinforcement members 602.

As shown in FIG. 20, each first reinforcement member 601 has a dimension L1 in the second direction x that is greater than the dimension of each of the two first edges 20A of each first semiconductor element 201. When two first imaginary lines VL1 extend in the third direction y and pass through the ends of the respective first edges 20A, each of these first imaginary lines VL1 intersects the two first reinforcement members 601 as viewed in the first direction z.

As shown in FIG. 20, each second reinforcement member 602 has a dimension L2 in the third direction y that is greater than the dimension of each of the two second edges 20B of each first semiconductor element 201. When two second imaginary lines VL2 extend in the second direction x and pass through the ends of the respective second edges 20B, each of these second imaginary lines VL2 intersects the two second reinforcement members 602 as viewed in the first direction z.

The following describes operation and effect of the semiconductor device A40.

The semiconductor device A40 includes a first die pad 101, a first semiconductor element 201 bonded to the first die pad 101, a sealing resin 50 covering the first semiconductor element 201, and a reinforcement member 60 bonded to the first die pad 101. The linear expansion coefficient of the reinforcement member 60 is smaller than that of the sealing resin 50. This configuration thus enables the semiconductor device A40 to reduce the thermal stress occurring at the interface between the first semiconductor element 201 and the sealing resin 50. Additionally, the semiconductor device A40 has a configuration in common with the semiconductor device A10, thereby achieving the same effect as the semiconductor device A10.

The reinforcement member 60 of the semiconductor device A40 includes a first reinforcement member 601 extending in the second direction x and a second reinforcement member 602 extending in the third direction y. The dimension L1 of the first reinforcement member 601 in the second direction x is greater than the dimension of the first edge 20A of the first semiconductor element 201. The dimension L2 of the second reinforcement member 602 in the third direction y is greater than the dimension of the second edge 20B of the first semiconductor element 201. This configuration reduces the thermal strain imposed on the first die pad 101 in both the second direction x and the third direction y. This prevents the first die pad 101 from experiencing an uneven distribution of thermal strain. Additionally, the first reinforcement member 601 and the second reinforcement member 602 are spaced apart from each other. The semiconductor device A40 offers greater flexibility than the semiconductor device A30 in arranging the reinforcement member 60 relative to the first die pad 101.

### Fifth Embodiment

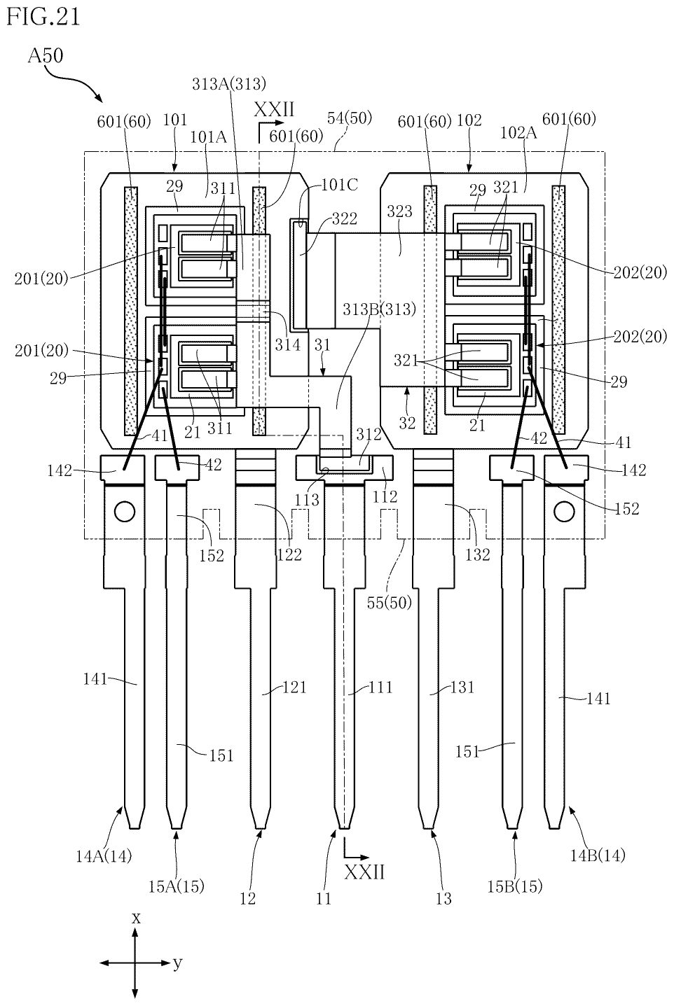

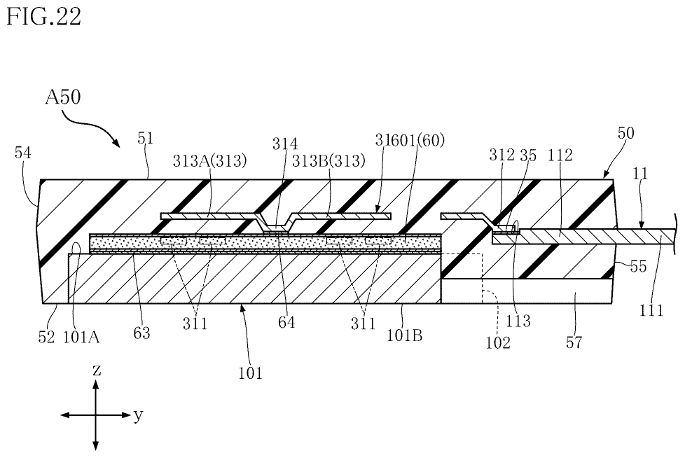

With reference to FIGS. 21 to 24, the following describes a semiconductor device A50 according to a fifth embodiment of the present disclosure. In these figures, elements identical or similar to those of the semiconductor device A10 described above are indicated by the same reference numerals, and redundant descriptions are omitted. For convenience, FIG. 21 shows the sealing resin 50 as transparent. FIG. 21 shows the outline of the sealing resin 50 by imaginary lines.

The semiconductor device A50 differs from the semiconductor device A10 in the configuration of the reinforcement member 60 that is bonded to the first die pad 101 among the two reinforcement members 60, as well as in the configuration of the first conductive member 31.

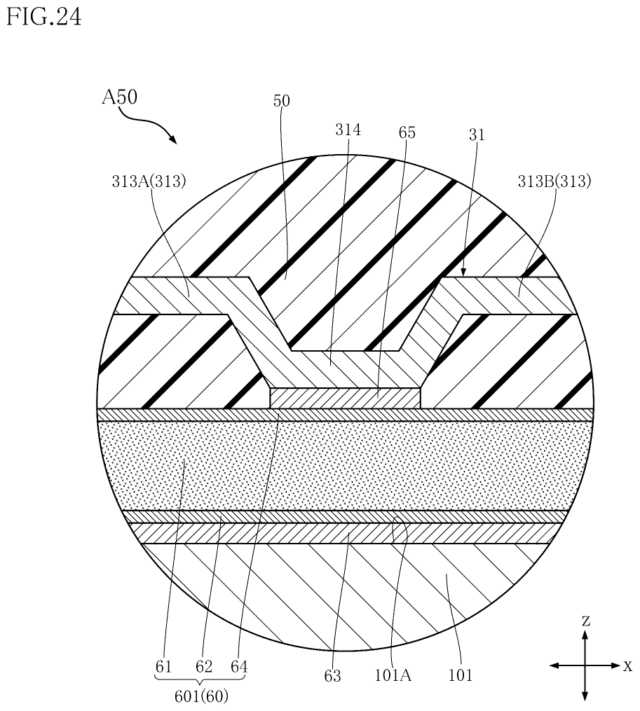

As shown in FIG. 24, the reinforcement member 60 includes a second metal layer 64. The second metal layer 64 is located on the side opposite the first metal layer 62 with respect to the insulating layer 61. The second metal layer 64 is stacked on the insulating layer 61. The second metal layer 64 contains copper or silver (Ag), for example. The second metal layer 64 may be formed by depositing a thin film of metal on the insulating layer 61 by sputtering. Alternatively, the reinforcement member 60 may be formed from a direct bonded copper (DBC) substrate.

As shown in FIGS. 21 and 22, the first conductive member 31 has a first intermediate portion 313 that includes a first portion 313A and a second portion 313B. The first portion 313A and the second portion 313B are spaced apart from each other. The first portion 313A is connected to the two first bonding portions 311 of the first conductive member 31. The second portion 313B is connected to the second bonding portion 312 of the first conductive member 31.

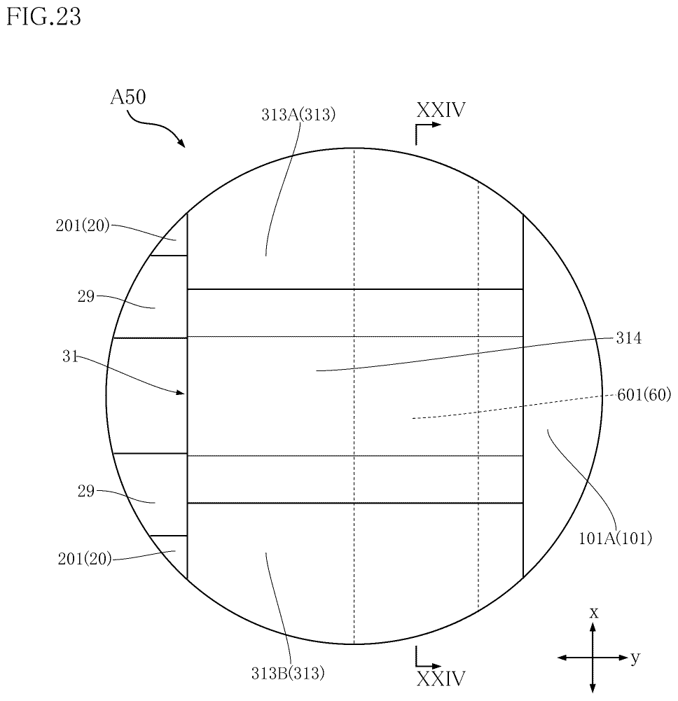

As shown in FIGS. 23 and 24, the first conductive member 31 includes a bend portion 314. The bend portion 314 connects the first portion 313A and the second portion 313B. The bend portion 314 protrudes from the first portion 313A and the second portion 313B toward the second metal layer 64 of the reinforcement member 60. The second metal layer 64 is bonded to the bend portion 314 via a second bonding layer 65. The second bonding layer 65 is solder, for example.

The following describes operation and effect of the semiconductor device A50.

The semiconductor device A50 includes a first die pad 101, a first semiconductor element 201 bonded to the first die pad 101, a sealing resin 50 covering the first semiconductor element 201, and a reinforcement member 60 bonded to the first die pad 101. The linear expansion coefficient of the reinforcement member 60 is smaller than that of the sealing resin 50. This configuration thus enables the semiconductor device A50 to reduce the thermal stress occurring at the interface between the first semiconductor element 201 and the sealing resin 50. Additionally, the semiconductor device A50 has a configuration in common with the semiconductor device A10, thereby achieving the same effect as the semiconductor device A10.

The reinforcement member 60 of the semiconductor device A50 includes a second metal layer 64 that is located on the side opposite the first metal layer 62 with respect to the insulating layer 61 and is stacked on the insulating layer 61. The second metal layer 64 is bonded to the first conductive member 31. This configuration allows heat conducted from the first semiconductor element 201 to the first conductive member 31 is further conducted to the first die pad 101 via the reinforcement member 60. This improves the heat dissipation efficiency of the semiconductor device A50 and also allows a larger electric current to pass the first conductive member 31. To facilitate faster heat conduction from the first conductive member 31 to the first die pad 101, the insulating layer 61 preferably has a higher thermal conductivity than the sealing resin 50.

The present disclosure is not limited to the embodiments described above. Various modifications in design may be made freely in the specific structure of each part according to the present disclosure.

The present disclosure includes embodiments described in the following clauses.

### Clause 1.

A semiconductor device comprising:
a first die pad;
a first semiconductor element bonded to the first die pad;
a sealing resin covering the first semiconductor element; and
a reinforcement member bonded to the first die pad,
wherein a linear expansion coefficient of the reinforcement member is smaller than a linear expansion coefficient of the sealing resin.

### Clause 2.

The semiconductor device according to Clause 1, wherein the reinforcement member is covered with the sealing resin.

### Clause 3.

The semiconductor device according to Clause 2, wherein the reinforcement member is located on a same side as the first semiconductor element in a first direction with respect to the first die pad.

### Clause 4.

The semiconductor device according to Clause 3, wherein the first semiconductor element includes a first edge extending in a second direction perpendicular to the first direction as viewed in the first direction, and
a dimension of the reinforcement member in the second direction is greater than a dimension of the first edge.

### Clause 5.

The semiconductor device according to Clause 4, wherein when two imaginary lines extend in a third direction perpendicular to the first direction and the second direction and pass through opposite ends of the first edge, each of the two imaginary lines intersects the reinforcement member as viewed in the first direction.

### Clause 6.

The semiconductor device according to Clause 5, wherein a dimension of the first die pad in the second direction is greater than a dimension of the first die pad in the third direction.

### Clause 7.

The semiconductor device according to Clause 5, wherein the reinforcement member surrounds the first semiconductor element as viewed in the first direction.

### Clause 8.

The semiconductor device according to any one of Clauses 4 to 7, wherein a dimension of the reinforcement member in the first direction is greater than a dimension of the first semiconductor element in the first direction.

### Clause 9.

The semiconductor device according to Clause 4, further comprising:
a first lead spaced apart from the first die pad; and
a first conductive member electrically bonded to each of the first semiconductor element and the first lead,
wherein the first conductive member is covered with the sealing resin.

### Clause 10.

The semiconductor device according to Clause 9, wherein the reinforcement member includes an insulating layer, and a first metal layer stacked on the insulating layer, and the first metal layer is bonded to the first die pad.

### Clause 11.

The semiconductor device according to Clause 10, wherein a portion of the sealing resin is located between the insulating layer and the first conductive member in the first direction.

### Clause 12.

The semiconductor device according to Clause 10, wherein the reinforcement member includes a second metal layer located on a side opposite the first metal layer with respect to the insulating layer and stacked on the insulating layer, and the second metal layer is bonded to the first conductive member.

### Clause 13.

The semiconductor device according to Clause 12, wherein a thermal conductivity of the insulating layer is higher than a thermal conductivity of the sealing resin.

### Clause 14.

The semiconductor device according to Clause 9, wherein the reinforcement member is made of metal.

### Clause 15.

The semiconductor device according to any one of Clauses 9 to 14, wherein the first semiconductor element is electrically bonded to the first die pad, the first die pad includes a first reverse surface facing away from the first semiconductor element in the first direction, and the first reverse surface is exposed from the sealing resin.

### Clause 16.

The semiconductor device according to Clause 15, further comprising:
a second die pad;
a second semiconductor element electrically bonded to the second die pad; and
a second conductive member electrically bonded to each of the second semiconductor element and the first die pad,
wherein the second semiconductor element and the second conductive member are covered with the sealing resin,
the second die pad includes a second reverse surface facing away from the first semiconductor element in the first direction, and
the second reverse surface is exposed from the sealing resin.

### Clause 17.

The semiconductor device according to Clause 16, further comprising:
a second lead connected to the first die pad; and
a third lead connected to the second die pad,
wherein the third lead is located on a side opposite the second lead with respect to the first lead, and
the first lead, the second lead, and the third lead each include a portion protruding from the sealing resin to outside.

### REFERENCE NUMERALS

A10, A20, A30, A40, A50: semiconductor device 101: first die pad 101A: first obverse surface 101B: first reverse surface 101C: first seat portion 102: second die pad 102A: second obverse surface 102B: second reverse surface 11: first lead 111: mounting portion 112: covered portion 113: second seat portion 12: second lead 121: mounting portion 122: covered portion 13: third lead 131: mounting portion 132: covered portion 14: fourth lead 14A: first gate terminal 14B: second gate terminal 141: mounting portion 142: covered portion 15: fifth lead 15A: first sense terminal 15B: second sense terminal 151: mounting portion 152: covered portion 20: semiconductor element 201: first semiconductor element 202: second semiconductor element 20A: first edge 20B: second edge 21: first electrode 22: second electrode 23: third electrode 24: fourth electrode 29: conductive bonding layer 31: first conductive member 311: first bonding portion 312: second bonding portion 313: first intermediate portion 313A: first portion 313B: second portion 314: bend portion 32: second conductive member 321: third bonding portion 322: fourth bonding portion 323: second intermediate portion 34: first conductive bonding layer 35: second conductive bonding layer 36: third conductive bonding layer 37: fourth conductive bonding layer 41: first wire 42: second wire 43: first relay wire 44: second relay wire 50: sealing resin 51: top surface 52: bottom surface 53: first side surface 54: second side surface 55: third side surface 56: recessed portion 57: trench 60: reinforcement member 601: first reinforcement member 602: second reinforcement member 61: insulating layer 62: first metal layer 63: first bonding layer 64: second metal layer z: first direction x: second direction y: third direction

1. A semiconductor device comprising:
a first die pad;
a first semiconductor element bonded to the first die pad;
a sealing resin covering the first semiconductor element; and
a reinforcement member bonded to the first die pad,
wherein a linear expansion coefficient of the reinforcement member is smaller than a linear expansion coefficient of the sealing resin.

2. The semiconductor device according to claim 1, wherein the reinforcement member is covered with the sealing resin.

3. The semiconductor device according to claim 2, wherein the reinforcement member is located on a same side as the first semiconductor element in a first direction with respect to the first die pad.

4. The semiconductor device according to claim 3, wherein the first semiconductor element includes a first edge extending in a second direction perpendicular to the first direction as viewed in the first direction, and
a dimension of the reinforcement member in the second direction is greater than a dimension of the first edge.

5. The semiconductor device according to claim 4, wherein when two imaginary lines extend in a third direction perpendicular to the first direction and the second direction and pass through opposite ends of the first edge, each of the two imaginary lines intersects the reinforcement member as viewed in the first direction.

6. The semiconductor device according to claim 5, wherein a dimension of the first die pad in the second direction is greater than a dimension of the first die pad in the third direction.

7. The semiconductor device according to claim 5, wherein the reinforcement member surrounds the first semiconductor element as viewed in the first direction.

8. The semiconductor device according to claim 4, wherein a dimension of the reinforcement member in the first direction is greater than a dimension of the first semiconductor element in the first direction.

9. The semiconductor device according to claim 4, further comprising:
a first lead spaced apart from the first die pad; and
a first conductive member electrically bonded to each of the first semiconductor element and the first lead,
wherein the first conductive member is covered with the sealing resin.

10. The semiconductor device according to claim 9, wherein the reinforcement member includes an insulating layer, and a first metal layer stacked on the insulating layer, and
the first metal layer is bonded to the first die pad.

11. The semiconductor device according to claim 10, wherein a portion of the sealing resin is located between the insulating layer and the first conductive member in the first direction.

12. The semiconductor device according to claim 10, wherein the reinforcement member includes a second metal layer located on a side opposite the first metal layer with respect to the insulating layer and stacked on the insulating layer, and
the second metal layer is bonded to the first conductive member.

13. The semiconductor device according to claim 12, wherein a thermal conductivity of the insulating layer is higher than a thermal conductivity of the sealing resin.

14. The semiconductor device according to claim 9, wherein the reinforcement member is made of metal.

15. The semiconductor device according to claim 9, wherein the first semiconductor element is electrically bonded to the first die pad,
the first die pad includes a first reverse surface facing away from the first semiconductor element in the first direction, and
the first reverse surface is exposed from the sealing resin.

16. The semiconductor device according to claim 15, further comprising:
a second die pad;
a second semiconductor element electrically bonded to the second die pad; and
a second conductive member electrically bonded to each of the second semiconductor element and the first die pad,
wherein the second semiconductor element and the second conductive member are covered with the sealing resin,
the second die pad includes a second reverse surface facing away from the first semiconductor element in the first direction, and
the second reverse surface is exposed from the sealing resin.

17. The semiconductor device according to claim 16, further comprising:
a second lead connected to the first die pad; and
a third lead connected to the second die pad,
wherein the third lead is located on a side opposite the second lead with respect to the first lead, and
the first lead, the second lead, and the third lead each include a portion protruding from the sealing resin to outside.
